(19) United States
(12) Patent Application Publication
(10) Pub. No.: US 2024/0412090 A1
(43) Pub. Date: Dec. 12, 2024

(54) INTERCONNECT CHIP AND L-COUPLER FOR MODULAR QUANTUM LINKS

(71) Applicant: International Business Machines Corporation, Armonk, NY (US)

(72) Inventors: Neereja Sundaresan, Mount Kisco, NY (US); Shawn Anthony Hall, Pleasantville, NY (US); Jason S. Orcutt, Katonah, NY (US); Jae-Woong Nah, Closter, NJ (US); Yves Martin, Ossining, NY (US); Wen-Sen Lu, Yorktown Heights, NY (US); John Michael Cotte, New Fairfield, CT (US)

(21) Appl. No.: 18/330,680

(22) Filed: Jun. 7, 2023

(51) Int. Cl. G06N 10/40

(52) U.S. Cl. CPC G06N 10/40

(57) ABSTRACT

Systems and techniques that facilitate coupling a superconducting cable to a interconnect chip and a quantum processor. In various embodiments, a system can comprise a quantum processor, one or more interconnect chips, and one or more cable connections. The quantum processor can comprise a plurality of qubits. Additionally, the one or more interconnect chips can be bonded to the quantum processor, and the one or more cable connections can be coupled to the one or more interconnect chips. With embodiments, the one or more interconnect chips can comprise one or more signal routings from the one or more cable connections to the quantum processor. Further, in embodiments, a first signal can pass from the one or more cable connections to at least one of the plurality of qubits.

### TECHNICAL FIELD

The present disclosure relates to interconnect chips disposed between superconducting quantum chips and substrates, and further, using one or more interconnect chips to mechanically and electrically support connecting one or more superconducting cables to the quantum chips; and an L-coupler to connect one or more superconducting cables to the quantum chips.

### BACKGROUND

Quantum processors are highly sensitive devices that operate in extremely controlled environments to harness the power of quantum mechanics. To facilitate building larger quantum processor, where not all components can fit on a single processor or substrate, quantum channels between quantum processors can be used; bringing physical microwave connections proximal to the quantum processor. However, when it comes to attaching connections near the quantum processor, many issues arise such as: the mechanical stress exerted on the quantum processor bond connections; the unintended microwave crosstalk between delicately shielded quantum processor components and the larger packaging environment of the connections, and degradation of quantum processor performance due to heat operations like soldering.

### SUMMARY

The following presents a summary to provide a basic understanding of one or more embodiments of the invention. This summary is not intended to identify key or critical elements. or delineate any scope of the particular embodiments or any scope of the claims. Its sole purpose is to present concepts in a simplified form as a prelude to the more detailed description that is presented later.

According to an embodiment, a system can comprise a quantum processor, one or more interconnect chips, and one or more cable connections. In one or more embodiments of the aforementioned system, the quantum processor can comprise a plurality of qubits. Further, in one or more embodiments of the aforementioned system, the one or more interconnect chips can be bonded to the quantum processor. The one or more cable connections can be coupled to the one or more interconnect chips. In one or more embodiments of the aforementioned system, the one or more interconnect chips can comprise one or more signal routings from the one or more cable connections to the quantum processor. Additionally, in one or more embodiments of the aforementioned system, a first signal can pass from the one or more cable connections to at least one of the plurality of qubits. In one or more embodiments of the aforementioned system, the quantum processor can be bonded to the one or more interconnect chips.

According to one or more additional embodiments of the aforementioned system, the one or more cable connections can comprise a reusable connection. In one or more embodiments of the aforementioned system, the reusable connection can comprise an outer layer which can comprise a machine solderable metal. Further, in one or more embodiments, the reusable connection can comprise an inner layer that can comprise a solderable metal. In one or more embodiments of the aforementioned system, the reusable connection can be configured to receive at least a center conductor of coax cable. Additionally, in one or more embodiments of the aforementioned system, a solder material inside the reusable connection can electrically connect a received coax cable to the one or more signal routings.

Further, according to one or more embodiments of the aforementioned system, the one or more cable connections can be configured to receive a low-loss cable. In one or more embodiments of the aforementioned system, the system can further comprise one or more through substrate vias coupled to a ground plane from the one or more interconnect chips. Additionally, in one or more embodiments of the aforementioned system, the one or more cable connections can be configured to receive a superconducting cable. In one or more embodiments, the quantum processor can comprise an interposer bonded to a quantum chip.

An advantage of the above-indicated system can be providing a modular quantum processor design with plug and play architecture. Further, coupling the one or more interconnect chips to the superconducting cable, and bonding the quantum processor to the one or more interconnect chips can relieve mechanical stress from the bond connection of the quantum processor. Relieving such mechanical stress can enable connections from the quantum processor to other quantum processors via indirectly or directly coupled superconducting cables. Additionally, coupling one or more interconnect chips between the substrate and the quantum processor can facilitate reducing or removing unintended microwave crosstalk due to interference with delicate quantum processor components.

According to another embodiment, a method can comprise attaching, via an adhesive, a interconnect chip to a substrate. Additionally, the method can comprise bonding a quantum processor to the interconnect chip. Further, the method can comprise coupling a superconducting cable to the interconnect chip. In one or more embodiment of the aforementioned method, the method can comprise attaching the superconducting cable directly to a surface of the interconnect chip. With embodiments of the aforementioned method, the method can comprise attaching a connector of the superconducting cable to a surface of the interconnect chip.

In one or more embodiments of the aforementioned method, the method can comprise bonding the quantum processor to the interconnect chip. Additionally, in one or more embodiments of the aforementioned method, the method can comprise milling a portion of the substrate prior to attaching the interconnect chip. In one or more embodiments of the aforementioned method, the method can comprise, after attaching the superconducting cable to a top surface of the interconnect chip, the interconnect chip can be substantially planar to a top surface of the substrate. In one or more embodiments of the aforementioned method, the method can comprise wherein bonding the quantum processor to the interconnect chip can further comprise bonding the quantum processor to the substrate.

An advantage of the above-indicated method can be providing a modular quantum processor design with plug and play architecture. Further, coupling the one or more interconnect chips to the superconducting cable, and bonding the quantum processor to the one or more interconnect chips can relieve mechanical stress from the bond connection of the quantum processor. Relieving such mechanical stress can enable connections from the quantum processor to other quantum processors via indirectly or directly coupled superconducting cables. Additionally, coupling one or more interconnect chips between the substrate and the quantum processor can facilitate reducing or removing unintended microwave crosstalk due to interference with delicate quantum processor components.

According to another embodiment, a coupling device can comprise an outer cylinder comprising a machinable metal and a solderable metal, wherein the coupling device can be configured to receive a first cable at a first end of the coupling device. In one or more embodiments of the aforementioned device, a second end of the coupling device can be capable of being soldered to a substrate. Additionally, in one or more embodiments of the aforementioned device, the device can comprise a second end of the coupling device can be capable of receiving a second cable. In one or more embodiments of the aforementioned device, the device can comprise an inner cylinder that can comprise the machinable metal and the solderable metal, and wherein the outer cylinder can be configured to connect to a shield of the first cable, and wherein the inner cylinder can be configured to connect to a center core of the first cable.

An advantage of the above-indicated device can be providing a modular quantum processor design with plug and play architecture. Further, coupling the one or more interconnect chips to the superconducting cable, and bonding the quantum processor to the one or more interconnect chips can relieve mechanical stress from the bond connection of the quantum processor. Relieving such mechanical stress can enable connections from the quantum processor to other quantum processors via indirectly or directly coupled superconducting cables. Additionally, coupling one or more interconnect chips between the substrate and the quantum processor can facilitate reducing or removing unintended microwave crosstalk due to interference with delicate quantum processor components.

### DESCRIPTION OF THE DRAWINGS

FIG. 1A illustrates a diagram of an example, non-limiting interconnect chip and L-coupler system, pre-assembly, that can facilitate coupling one or more quantum processors with a low-loss cable in accordance with one or more embodiments described herein.

FIG. 1B illustrates a diagram of an example, non-limiting interconnect chip and L-coupler system, post-assembly, that can facilitate coupling one or more quantum processors with a low-loss cable in accordance with one or more embodiments described herein.

FIG. 2A illustrates a diagram of an example, non-limiting interconnect chip and L-coupler system, post-assembly, that can facilitate coupling one or more quantum processors with a low-loss cable in accordance with one or more embodiments described herein.

FIG. 2B illustrates a diagram of an example, non-limiting interconnect chip and L-coupler system, post-assembly, that can facilitate coupling one or more quantum processors with a low-loss cable in accordance with one or more embodiments described herein.

FIG. 3 illustrates a diagram of an example, non-limiting interconnect chip and L-coupler system, during the assembly process, that can facilitate coupling one or more quantum processors with a low-loss cable in accordance with one or more embodiments described herein.

FIG. 4 illustrates a diagram of an example, non-limiting interconnect chip and L-coupler system, during the assembly process, that can facilitate coupling one or more quantum processors with a low-loss cable in accordance with one or more embodiments described herein.

FIG. 5 illustrates a diagram of an example, non-limiting interconnect chip and L-coupler system, during the assembly process, that can facilitate coupling one or more quantum processors with a low-loss cable in accordance with one or more embodiments described herein.

FIG. 6 illustrates a diagram of an example, non-limiting interconnect chip and L-coupler system, post-assembly, that can facilitate coupling one or more quantum processors with a low-loss cable in accordance with one or more embodiments described herein.

FIG. 7A illustrates a diagram of an example, non-limiting interconnect chip and L-coupler system including a coupler, pre-assembly, that can facilitate coupling one or more quantum processors with a low-loss cable in accordance with one or more embodiments described herein.

FIG. 7B illustrates a diagram of an example, non-limiting interconnect chip and L-coupler system including a coupler, post-assembly, that can facilitate coupling one or more quantum processors with a low-loss cable in accordance with one or more embodiments described herein.

FIG. 8 illustrates a diagram of an example, non-limiting interconnect chip and L-coupler system including a coupler, pre-assembly, that can facilitate coupling one or more quantum processors with a low-loss cable in accordance with one or more embodiments described herein.

FIG. 9 illustrates a diagram of an example, non-limiting interconnect chip and L-coupler system including a coupler, pre-assembly, that can facilitate coupling one or more quantum processors with a low-loss cable in accordance with one or more embodiments described herein.

FIG. 10A illustrates a diagram of an example, non-limiting interconnect chip and L-coupler system including a coupler having an inner layer and an outer layer, that can facilitate coupling one or more quantum processors with a low-loss cable in accordance with one or more embodiments described herein.

FIG. 10B illustrates a diagram of an example, non-limiting interconnect chip and L-coupler system including a coupler having an inner layer and an outer layer, that can facilitate coupling one or more quantum processors with a low-loss cable in accordance with one or more embodiments described herein.

FIG. 11 illustrates a diagram of an example, non-limiting interconnect chip and L-coupler system including a coupler connecting two superconducting cables together, that can facilitate coupling one or more quantum processors in accordance with one or more embodiments described herein.

FIG. 12 illustrates a flowchart of an example, non-limiting method that can facilitate coupling one or more quantum processors in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, where like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

As used herein, a quantum circuit can be a set of operations, such as gates, performed on a set of real-world physical qubits with the purpose of obtaining one or more qubit measurements. A quantum processor can comprise the one or more real-world physical qubits. A quantum processor can include a quantum circuit module consisting of one or more qubits, control lines for driving one or more gates, output lines for reading one or more qubit states, and coupling between qubits to enable complex multi-qubit circuits. Quantum processors can consist of two or more nanofabricated chips (interposer chip and qubit chip) and all input/output can be funneled via the interposer chip to a substrate (e.g., a circuit board).

As used herein, a quantum L-coupler interconnect can facilitate a coupling pathway to couple two or more physically distinct quantum processors such that quantum coherent operation between qubits on different processors can occur. The Long-coupler (“L-coupler) can be long (e.g., relative to microwave wavelength) indicating that the one or more connected quantum processors can be separated by some long channel.

Quantum processor can include qubit chips configured to transmit a variety of quantum/qubit states. Qubit states only can exist (or can only be coherent) for a limited amount of time. Thus, an objective of operation of a quantum logic circuit (e.g., including one or more qubits) can be to maximize the coherence time of the employed qubits. Time spent to operate the quantum logic circuit can undesirably reduce the available time of operation on one or more qubits. This can be due to the available coherence time of the one or more qubits prior to decoherence of the one or more qubits. For example, a qubit state can be lost in less than 100 to 200 microseconds in one or more cases.

Quantum processors can consist of numerous delicate components, such as qubits and their associated control elements, which can require precise and stable interconnections, such as to not interfere with various quantum operations. Soldering connections, though commonly employed for their reliable electrical and mechanical properties, can introduce the potential for mechanical stress on these bond connections. The application of heat and subsequent cooling during the soldering process can induce thermal expansion and contraction, leading to mechanical strain on the quantum processor bond connections. Such stress can adversely affect the performance and reliability of the quantum processor, potentially resulting in degradation of quantum coherence and quantum computational errors.

Further, quantum processors often operate in environments with strict electromagnetic shielding and control to minimize external interference. However, the introduction of one or more large (relative to microwave wavelengths) cables, connectors, and signal paths, can inadvertently give rise to unintended microwave crosstalk between delicate quantum processor components and quantum information supported by the cable. This crosstalk can occur by proximity, which can lead to undesired effects, such as alteration of qubit states, introduction of errors, or even the potential damage to quantum coherence. Thus, separating the large components of the L-coupler on a separate interconnect chip can provide a physical distance between the delicate electromagnetic environment of the quantum processor and the L-coupler.

Conventional methods of connecting quantum processors over long ranges typically involves the use of quantum repeaters or entanglement swapping techniques. While these approaches have shown promising results in achieving entanglement distribution between quantum systems, they suffer from inherent limitations that hinder their practical application. These limitations include high error rates, susceptibility to environmental disturbances, and difficulties in scaling the interconnection network.

Furthermore, the transfer of quantum information over long distances often leads to a loss of quantum coherence, resulting in degraded computational performance and reduced quantum advantage. The loss of coherence arises from various sources, such as transmission losses, decoherence due to environmental factors, and imperfect entanglement swapping processes. Therefore, it can be desirable to enable the interconnection of multiple quantum processors over long ranges in a low-loss manner, ensuring the preservation of quantum coherence and minimizing error rates.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Further, the embodiments depicted in one or more figures described herein are for illustration only, and as such, the architecture of embodiments is not limited to the systems, devices and/or components depicted therein, nor to any particular order, connection and/or coupling of systems, devices and/or components depicted therein. In one or more described embodiments, computer and/or computing-based elements can be used in connection with implementing one or more of the systems, devices, components and/or computer-implemented operations shown and/or described in connection with the figures described herein.

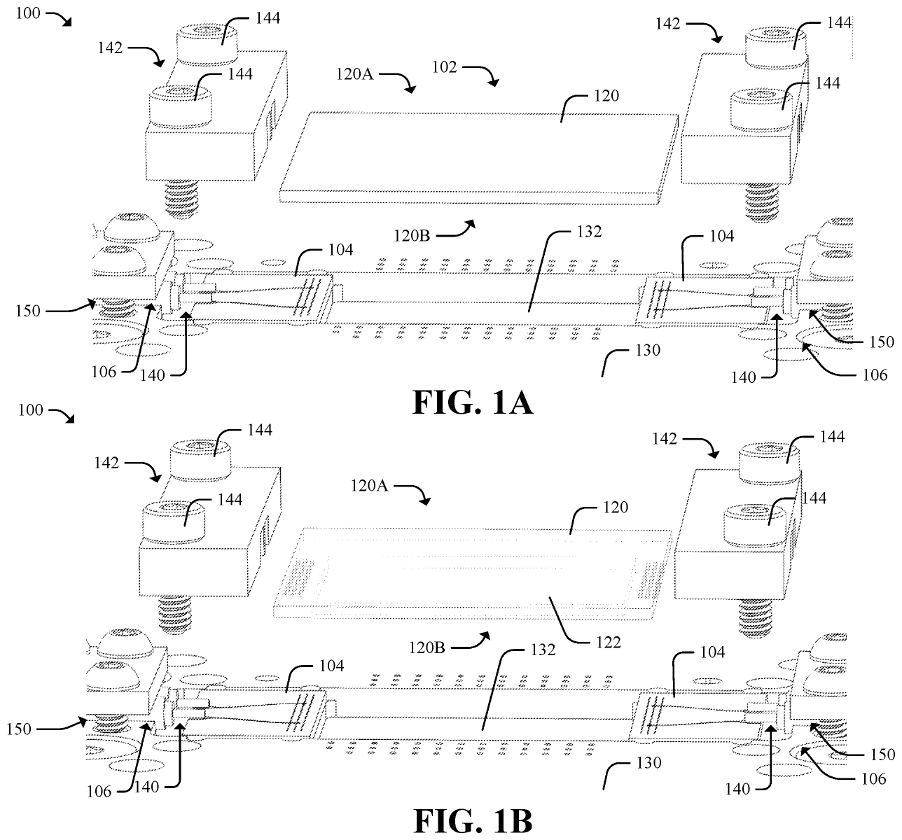

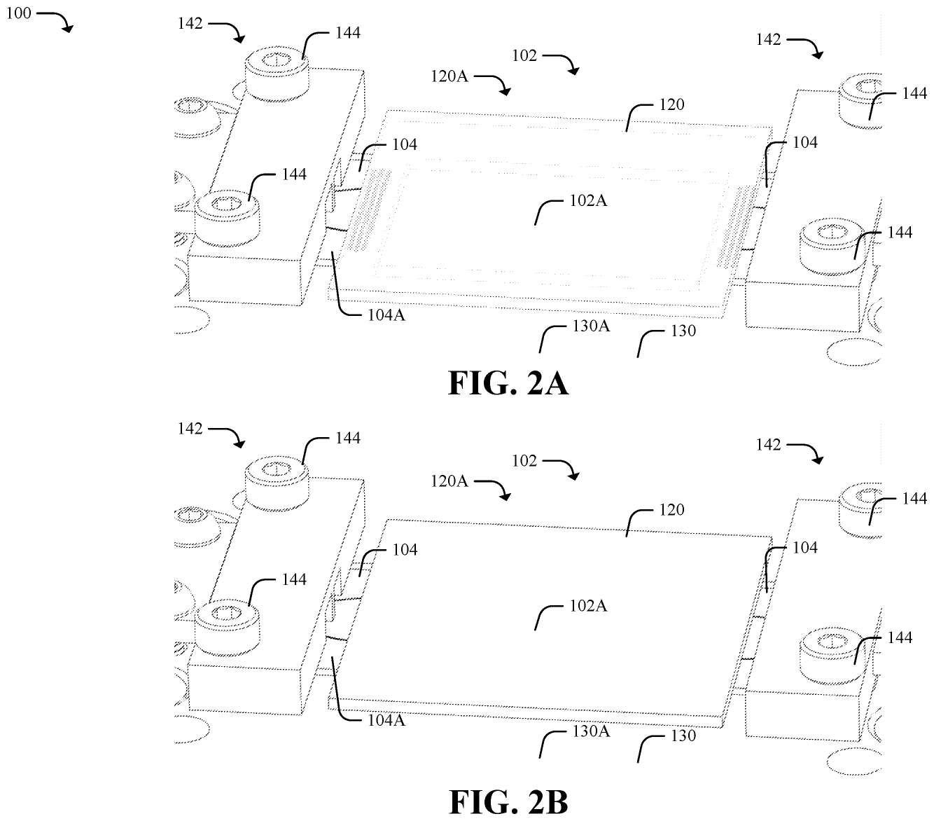

Turning first generally to FIG. 1A and 1B, the interconnect chip and L-coupler system 100 can include a quantum processor 102, one or more interconnect chips 104, and one or more cable connections 106 coupled to the one or more interconnect chips 104. Further, the one or more cable connections 106 can include one or more low-loss cables (e.g., low-loss can correspond with cables including a coaxial cable in which the core and the shield can be superconducting and little to no loss occurs between the core and shield) and/or one or more low-loss couplers. The quantum processor 102 can comprise a plurality of qubits (e.g., which can include any number); and the one or more interconnect chips 104 can be bonded to the quantum processor 102. Further, the one or more interconnect chips 104 can comprise one or more signal routings from the one or more cable connections 106 to the quantum processor 102 to execute quantum operations. The one or more signal routings can include a first signal that can pass from the one or more cable connections 106 to at least one of the plurality of qubits of the quantum processor 102. The one or more embodiments of FIGS. 1A and 1B illustrate the interconnect chip and L-coupler system 100 prior to assembly; and a similar nature, the one or more embodiments of FIGS. 2A and 2B illustrate the interconnect chip and L-coupler system 100 post-assembly.

With examples, the quantum processor 102 can include the plurality of qubits which can include any number of qubits to facilitate quantum operations carried out via interconnect chip and L-coupler system 100. In examples, the quantum processor 102 can include an interposer chip 120 and a qubit chip 122. The qubit chip 122 can be bonded to the interposer chip 120 such that the qubit chip 122 can be electrically coupled to the one or more interconnect chips 104 (e.g., one or more signal routings can pass from the one or more cable connections to the qubit chip 122). In examples, the one or more interconnect chips 104 can be configured to receive a connection. The one or more interconnect chips 104 can receive a connection such that the mechanical stress/interaction between the connection and the interconnect chip 104 does not interfere with the quantum processor 102 (e.g., operations of the qubit chip 122).

In embodiments, the one or more interconnect chips 104 can relieve/isolate mechanical stress that can be experienced by the quantum processor 102 (e.g., the more sensitive electrical components of the system 100) in securing connections to the quantum processor 102 (e.g., via soldering, coupling via heat, coupling via adhesives, etc.). For example, such mechanical stress between the quantum processor 102 and an exterior connection (e.g., a soldered cable, a connector, etc. via the cable connections 106) can be displaced to the interface between the one or more interconnect chips 104 and the exterior connection (e.g., a coupler or cable). The one or more interconnect chips 104 can manage the mechanical connection facilitating the electrical connection between a superconducting cable and the quantum processor 102 such that one or more signal routings can pass from the one or more cable connections 106 to the qubit chip 122. The one or more interconnect chips 104 can include substantially the same material as the qubit chip 122, which can be one or more of a variety of high-Q materials. Further, in one or more embodiments, the one or more signal components of the system 100 can be superconducting materials (e.g., Nb, Al, Ta, Ti, In, Sn, Pb, Ru, Rh, SnPb, SnAu, ReMo, NbTi, etc.). The superconducting materials or near superconducting materials can be used for wiring (e.g., sending signals) and components (e.g., connectors, qubits, resonators, etc.) included with the interconnect chip and L-coupler system 100. With embodiments, further related operations and components (e.g., stripline wiring) can additionally include superconducting materials.

With embodiments, such as illustrated in FIGS. 1A and 1B, the interconnect chip and L-coupler system 100 can include a substrate 130 that which the quantum processor 102 can be coupled to. The interposer chip 120 can include a top surface 120A and a bottom surface 120B, and the top surface 120A can be disposed opposite to the bottom surface 120B. Further, the qubit chip 122 can be bonded to the bottom surface 120B of the interposer chip 120 (see, e.g., FIG. 1B). In one or more embodiments, the substrate 130 can include a cavity 132 that can be disposed in a center of the substrate 130. The cavity 132 can be one or more of a variety of shapes, sizes, and/or configurations. For example and without limitation, the cavity 132 can be substantially rectangular shaped. The qubit chip 122 (e.g., the quantum processor 102) can be disposed such that the qubit chip 122 (e.g., the quantum processor) can be aligned in at least one direction with the cavity 132. For example, the qubit chip 122 can be aligned in a vertical direction with the cavity 132 such that the qubit chip 122 can be disposed over the cavity 132 and/or within a perimeter of the cavity 132.

Additionally, in further embodiments, the quantum processor 102 (e.g., the qubit chip 122 and the interposer chip 120), the one or more interconnect chips 104, and the substrate 130 can be aligned to be disposed in a substantially parallel manner to effectuate connections and couplings therebetween. Further, parallel alignment of the quantum processor 102, the one or more interconnect chips 104, and the substrate 130 can facilitate electrical connections therebetween via a variety of bonding processes.

With embodiments, the interconnect chip and L-coupler system 100 can include a coupling device 140. The coupling device 140 can couple a cable 150 (e.g., a superconducting cable) coupled to the quantum processor 102 via the one or more interconnect chips 104. Further, the coupling device 140 can be secured/reinforced to the one or more interconnect chips 104 via a bridge 142. In one or more embodiments, the bridge 142 can include one or more of a variety of materials and configurations. For example, the bridge 142 can be solder plated, and the bridge 142 can be substantially rectangular (e.g., to align with the qubit chip 122, the one or more interconnect chips 104, and the substrate 130). The bridge 142 can be fastened to the substrate 130 via one or more fastening elements 144, which can be configured to penetrate a surface of the substrate 130.

In embodiments, as illustrated in FIGS. 1A, 1B, 2A, and 2B, during assembly of the interconnect chip and L-coupler system 100, surfaces of the quantum processor 102, the one or more interconnect chips 104, and the substrate 130 can be substantially parallel such that bonding and applying adhesives can be performed with minimal error from misalignment. During assembly, the one or more interconnect chips 104 can be substantially co-planar with the substrate 130 such that the quantum processor 102 bonds with the substrate 130 and the one or more interconnect chips 104 at substantially the same time. Misalignment of the quantum processor 102 with the one or more interconnect chips 104 and/or the substrate 130 can be responsible for diminished quantum processor 102 performance. As can be seen by FIGS. 2A and 2B, a top surface 102A of the quantum processor 102 can be substantially parallel with a top surface 104A of the one or more interconnect chips 104, and a top surface 130A of the substrate 130.

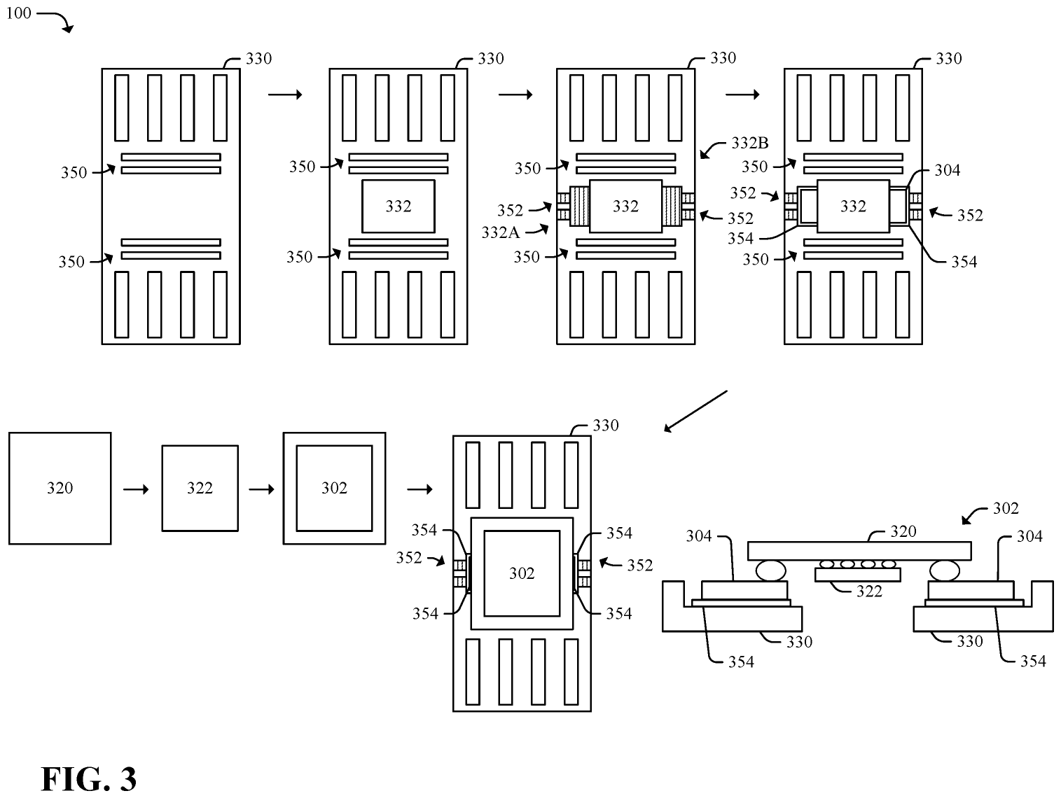

With embodiments, such as generally illustrated in FIG. 3, the interconnect chip and L-coupler system 100 can include the substrate 330. The substrate 330 can include one or more of a variety of electrical connection portions. For example and without limitation, the substrate 330 can include one or more patterned portions 350 of substrate 330 to couple with the quantum processor 302 (e.g., when bonding the quantum processor 302 with the one or more interconnect chips 304). With embodiments, a second signal can pass from the substrate 330 to the quantum processor 302 (e.g., via the one or more patterned portions 350), while the first signal can pass from the one or more interconnect chips 304 to the quantum processor 302. Further, the one or more interconnect chips 304 can include one or more through substrate vias coupled to a ground plane (e.g., providing a grounding source for the quantum processor 302. The substrate 330 can include the cavity 332, which can include one or more of a variety of shapes, sizes, and/or configurations. The cavity 332 can be substantially rectangular shaped such that the quantum processor 302 can be disposed within the perimeter of the cavity 332 in at least one direction (e.g., the vertical direction). In embodiments, the shape of the cavity 332 can be similar to the shape of the quantum processor 302. Additionally, the substrate 330 can further include one or more milled portions 352 that can facilitate electrical connections. Such connections can be between the quantum processor 302 and the substrate 330, between the substrate 330 and an exterior electrical component, and/or between the quantum processor 302 and an exterior electrical component. The milled portions 352 can be locations for the quantum processor 302 and the one or more interconnect chips 304 to be electrically connected with.

In embodiments, such as illustrated in FIG. 3, the interconnect chip and L-coupler system 100 can include the one or more interconnect chips 304 attached to the substrate 330. The one or more interconnect chips 304 can be disposed on a first side 332A and a second side 332B of the cavity 332 (e.g., the first side 332A can be opposite the second side 332B). Further, the one or more interconnect chips 304 can be attached to the substrate 330 via an adhesive 354. The adhesive 354 can be disposed between the one or more interconnect chips 304 and the substrate 330; and further, the adhesive 354 can improve the mechanical load from connecting a cable that may be transferred to quantum processor 302 via the one or more interconnect chips 304; and further, the adhesive 354 can permit connections to be secured directly to the one or more interconnect chips 304 separately from bonding the substrate 330 with the quantum processor 302. The adhesive 354 can include one or more of a variety of adhesive materials including mechanical properties sufficient to relieve mechanical stress and interference from effecting the quantum processor 302.

With embodiments, the qubit chip 322 can be bonded (e.g., bump bonded) with the interposer chip 320. As shown in FIGS. 1A, 1B, 2A, and 2B, the qubit chip 322 can be bonded to a bottom surface of the interposer chip 320. The bonding of the qubit chip 322 with the interposer chip 320 can occur separately, before, or after connecting the substate 330 with the one or more interconnect chips 304 in assembling the interconnect chip and L-coupler system 100. In response to attaching the one or more interconnect chips 304 to the substrate 330, the quantum processor 302 can be bonded (e.g., bump bonded, flip bonded, etc.) to the one or more interconnect chips 304.

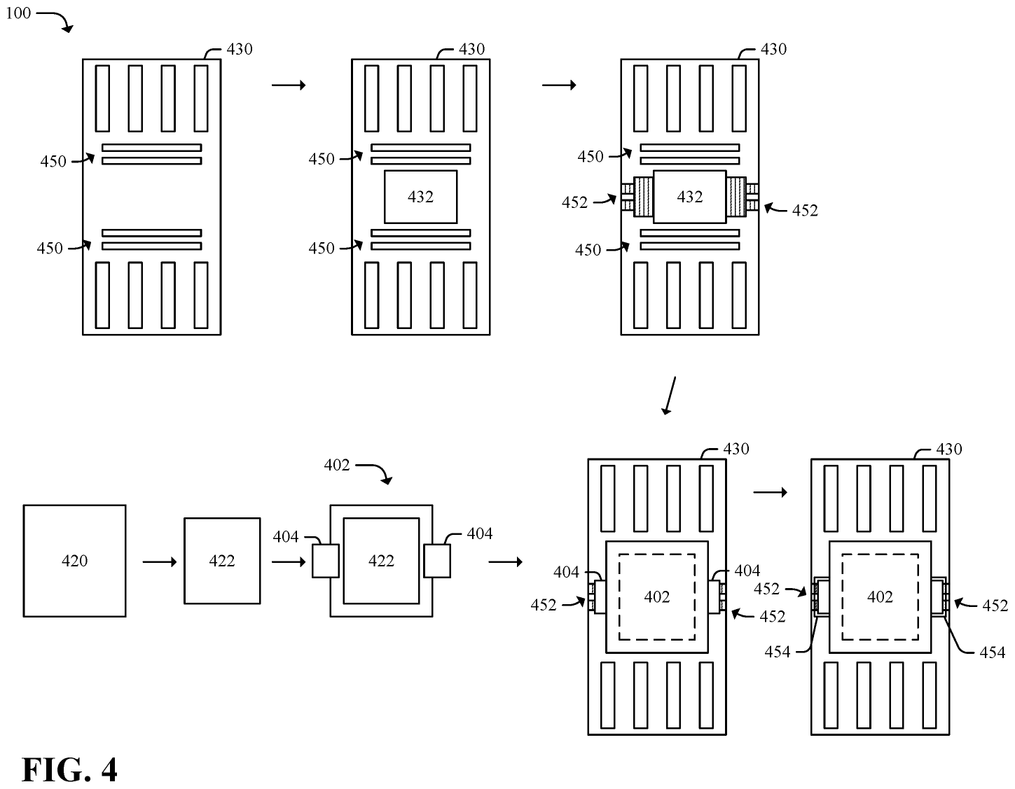

In embodiments, such as generally illustrated in FIG. 4, the interconnect chip and L-coupler system 100 can include the substrate 430, the one or more electrical connection portions 450, and the one or more milled portions 452. The interposer chip 422 can be bonded (e.g., bump bonding, flip bonding, etc.) with the qubit chip 420 to form the quantum processor 302. In response to forming the quantum processor 402, the one or more interconnect chips 404 can be bonded with the quantum processor 402 (e.g., the interposer chip 420). Following coupling the quantum processor 402 with the one or more interconnect chips 404, the one or more interconnect chips 404 can be flip bonded to the substrate 430, more specially, to the milled portions 452. In response, the adhesive 454 can be disposed between the substrate 430 and the one or more interconnect chips 404. Further, in response to dispensing/applying the adhesive 454, the adhesive 454 can be cured forming mechanical support for external cables (e.g., or a coupling device) to electrically connect with the quantum processor 402 via the one or more interconnect chips 404.

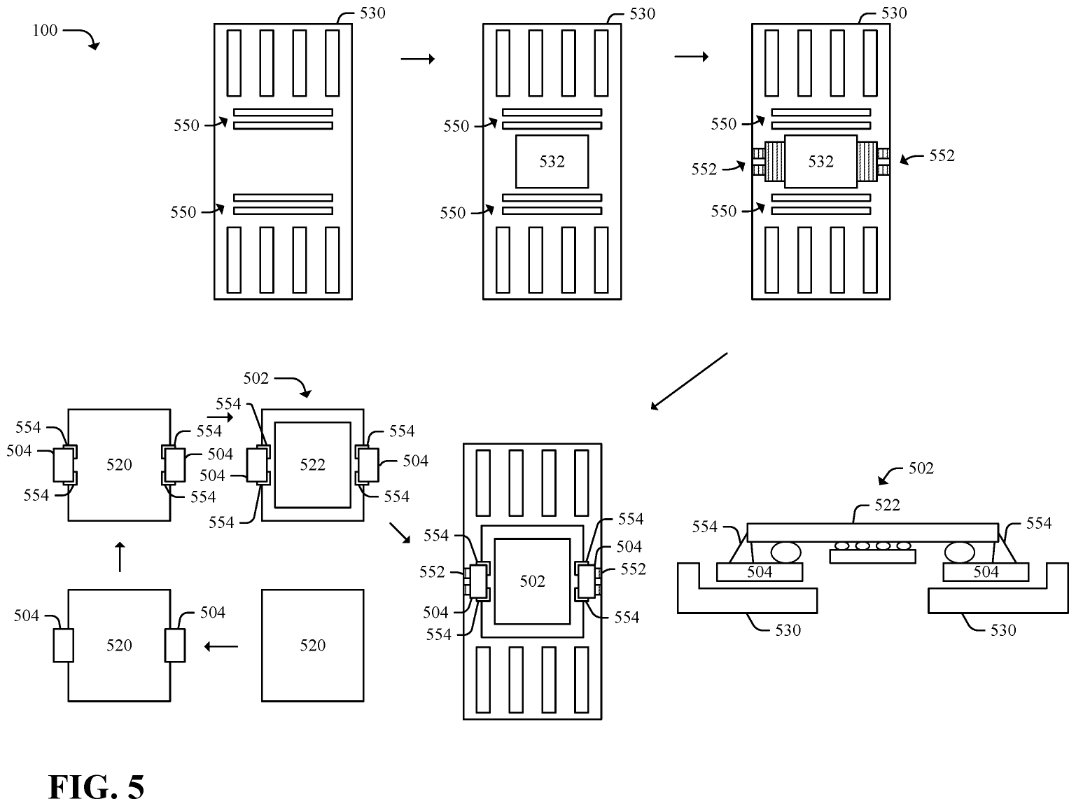

With embodiments, such as generally illustrated in FIG. 5, the interconnect chip and L-coupler system 100 can include the substrate 530, the one or more electrical connection portions 550, and the one or more milled portions 552. Further, the one or more interconnect chips 504 can be connected to the interposer chip 520 via bonding (e.g., bump bonding, flip bonding, etc.). In response to the one or more interconnect chips 504 bonding with the interposer chip 520, the adhesive 554 can be dispensed between the one or more interconnect chips 504 and the interposer chip 520. The adhesive 554 can be disposed between the quantum processor 502 and the one or more interconnect chips 504 such that the mechanical load of connections can be supported by the adhesive 554 and electrical connections can be supported via the bump bond.

In embodiments, such as can be seen in FIG. 5, the one or more interconnect chips 504 can be bonded to the interposer chip 520 prior to bonding the qubit chip 522 to the interposer chip 520. The one or more interconnect chips 504 can be bonded (e.g., bump bonded, flip bonded, etc.) to the quantum processor 502 prior to connecting the one or more interconnect chips 504 to the substrate 530 (e.g., to the milled portions 552). In examples, the one or more interconnect chips 504 (e.g., connected to the interposer chip and the qubit chip) can be attached to the substrate 530. In response to the adhesive 554 curing between the one or more interconnect chips 504 and the interposer chip 520, the one or more interconnect chips 504 can be flip bonded and/or bump bonded with the milled portions 552 of the substrate 530.

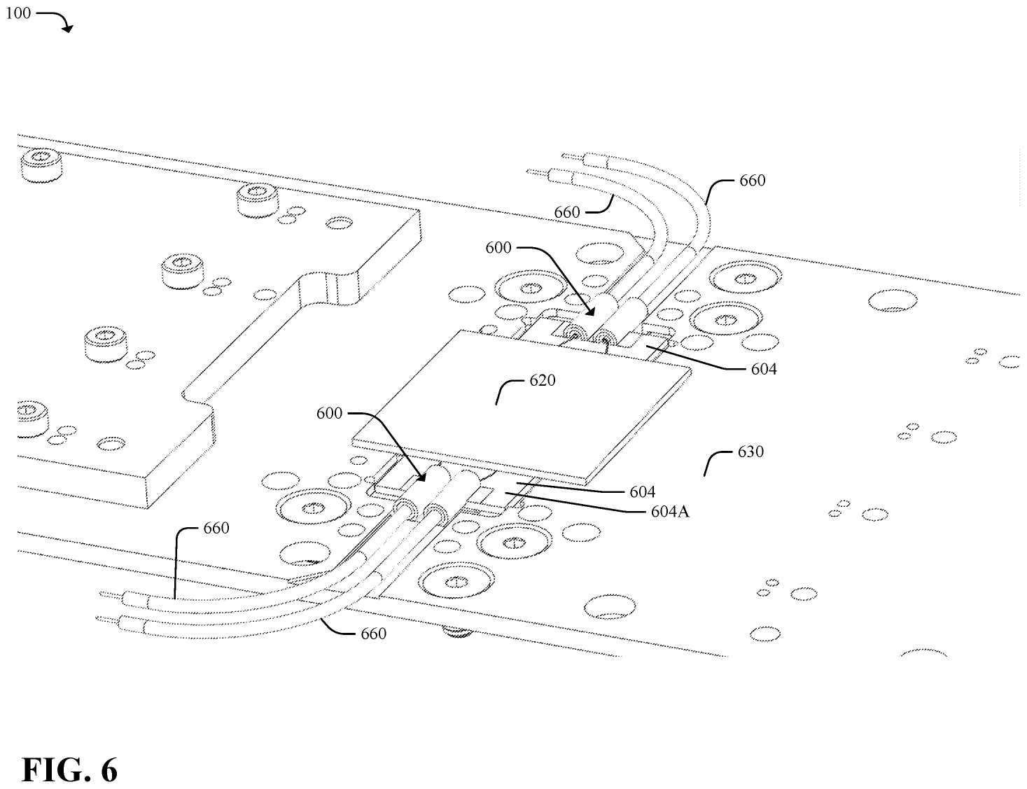

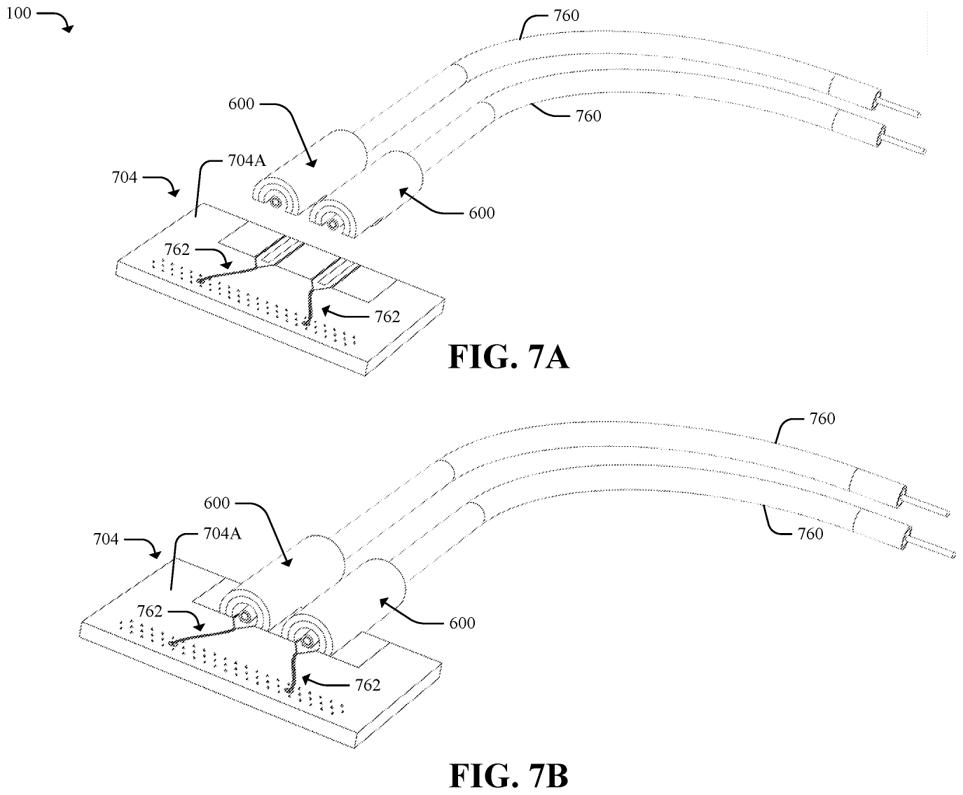

With embodiments, such as generally illustrated in FIG. 6, 7A, and 7B, the interconnect chip and L-coupler system 100 can include a coupling device 600. The coupling device 600 can provide a low-loss connection between the quantum processor 602 and one or more cables 660 (e.g., two cables) connected to the coupling device 600. In embodiments, the one or more cables 660 can be superconducting to facilitate low-loss connections. The coupling device 600 can be coupled to the one or more interconnect chips 604 prior to bonding the quantum processor 602 to the one or more interconnect chips 604. Bonding the coupling device 600 with the one or more interconnect chips 604 can include using flux for soldering, applying high heat, and other abrasive attaching methods (e.g., which can interfere with the quantum processor 602 if performed in close proximity). Additionally, rigorous surface cleans can be used to clean the interposer chip 620 without compromising performance of the quantum processor 602 or the low-loss connection via the coupling device 600. The coupling device 600 can be disposed between the one or more cables 660 and the one or more interconnect chips 604 (e.g., as shown in FIGS. 7A and 7B) such that a signal can pass from the one or more cables 660 to the coupling device 600, to the one or more interconnect chips 604, to the interposer chip 620, and to the qubit chip 622 in a substantially low-loss manner (e.g., where superconducting components can be used to facilitate low-loss connections).

In one or more embodiments, a conductor of the one or more cables 660 can be attached directly to the top surface 604A of the one or more interconnect chips 604 as an addition or alternative to connecting via the coupling device 600.

In embodiments, such as illustrated in FIGS. 7A and 7B, the coupling device 600 can be a reusable connection that can be connected and disconnected from the one or more interconnect chips 704 without interfering with the quantum processor (e.g., with minimal soldering or curing). Additionally, the one or more interconnect chips 704 can include one or more signal routings 762 that can electrically couple the coupling device 600 to the one or more interconnect chips 704 (e.g., the substrate 630 and the quantum processor 602). The one or more signal routings 762 can be disposed on the top surface 704A of the one or more interconnect chips 704 to bond with a substantially planar portion of the coupling device 600.

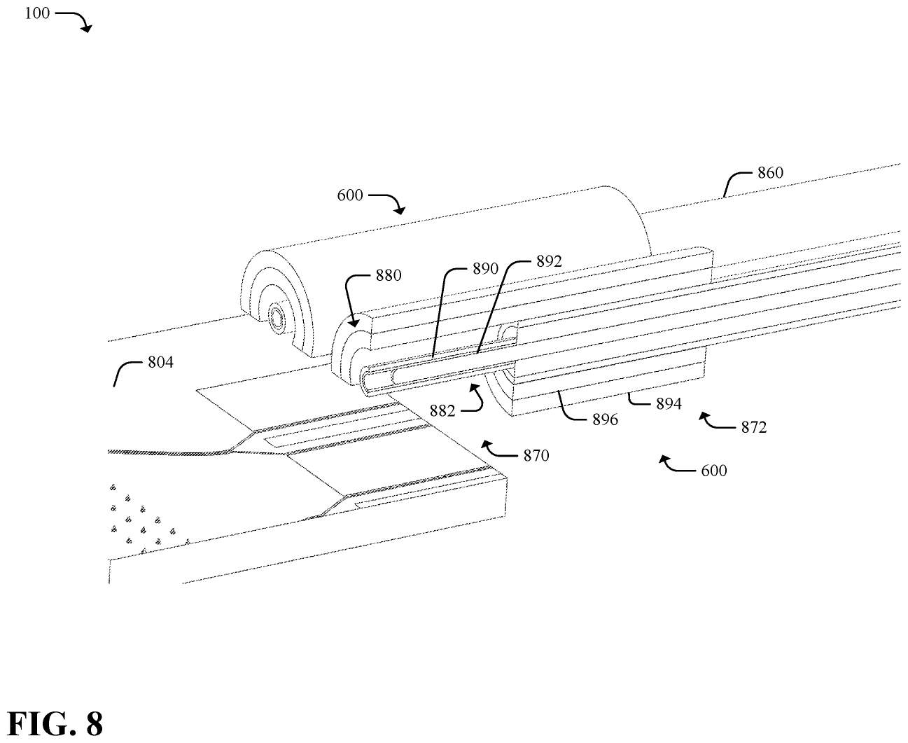

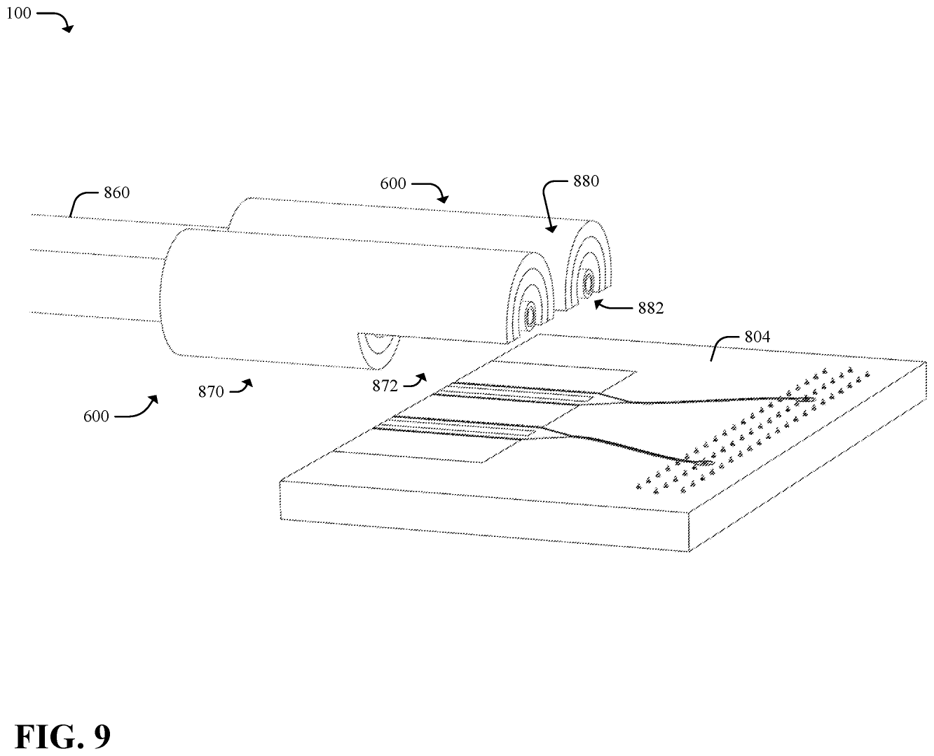

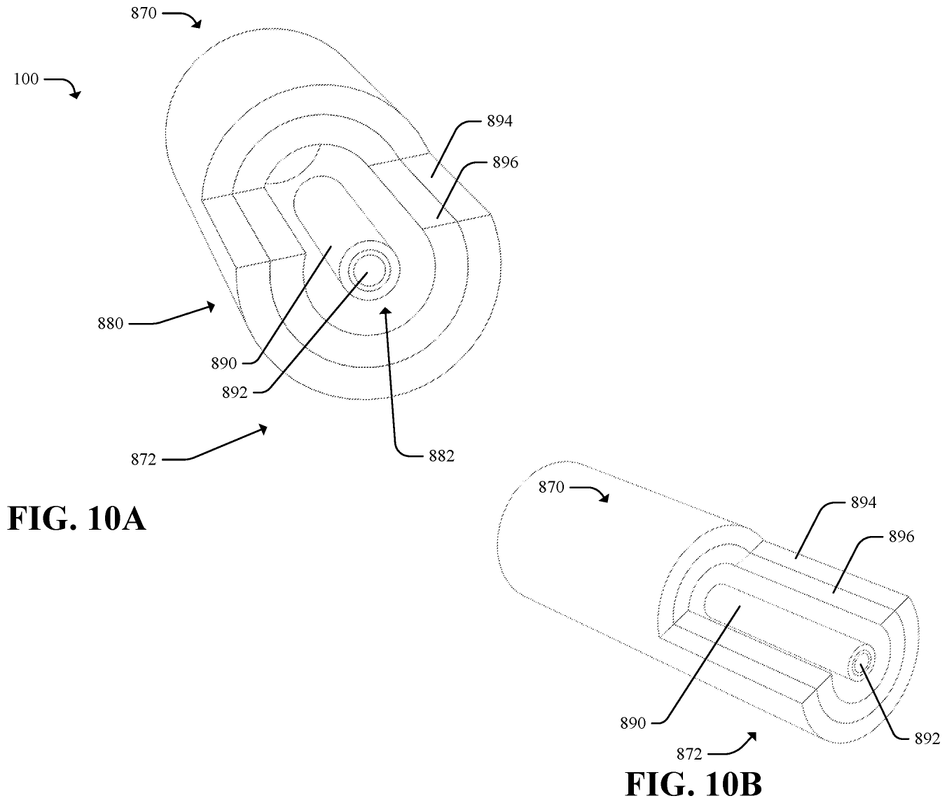

With embodiments, such as generally illustrated by FIGS. 8, 9, and 10, the coupling device 600 can include a first end 870 and a second end 872. The first end 870 of the coupling device 600 can be configured to receive a cable 760 (e.g., of the one or more cables 760). Further, the second end 872 of the coupling device 600 can be capable of being soldered to the one or more interconnect chips 804. The first end 870 of the coupling device 600 can include a substantially cylindrical shape. The second end 872 of the coupling device 600 can include a planar portion. In examples, the planar portion can be in contact with the one or more interconnect chips 804 (e.g., where an inside of the one or more cables can be exposed for electrical connection). The coupling device can include an outer layer 880 and an inner layer 882. The outer layer 880 and the inner layer 882 can include one or more of a variety of shapes, sizes, and configurations. For example and without limitation, the outer layer 880 and the inner layer 882 can be substantially cylinder shaped and the inner layer 882 be disposed within the outer layer 880.

In embodiments, the inner layer 882 and the outer layer 880 can include one or more of a variety of materials. For example and without limitation, the inner layer 882 can include a machinable metal 890 (e.g., Cu, BeCu Ti, Al, a stainless alloy, brass, etc.) and a solderable metal 892 (e.g., such as Pb, Sn, In, Zn, Bi, Cd, Sb, Ag, Au, Pt, Re, Rh, Cu, Ni, etc.) with the advantages that these materials are used to electrically connect one or more components together to electrically communicate and can become superconductors at low temperature, either by themselves, or as alloys (for example AuSn). Similarly, the outer layer 880 can also include a second machinable metal 894 and a second solderable metal 896. The one or more cables 860 connected to the coupling devices 600 can be one or more of a variety of cables. For example and without limitation, the one or more cables 860 can be coaxial cables, twisted pairs, waveguides, and/or superconducting cables. The coupling device 600 can include one or more of a variety of superconducting materials and one or more of a variety of dielectric materials (e.g., low-density Teflon, Si, Sapphire, etc.). Such superconducting materials can be included within the coupling device 600, the quantum processor 602, the one or more interconnect chips 604, the substrate 630, and the one or more cables 660; and further, superconducting materials can facilitate low-loss connections. The low-loss connections can further be supported in a low-loss manner by coupling superconducting cables (low-loss cables) to transmit quantum information between separately packaged quantum processors and/or quantum systems. Further, the one or more interconnect chips 604 can provide a low-loss superconducting connection interface between the quantum processor 602 and one or more of a variety of connectors, wires, and/or components (e.g., the coupling device 600) connected with the interconnect chip 604.

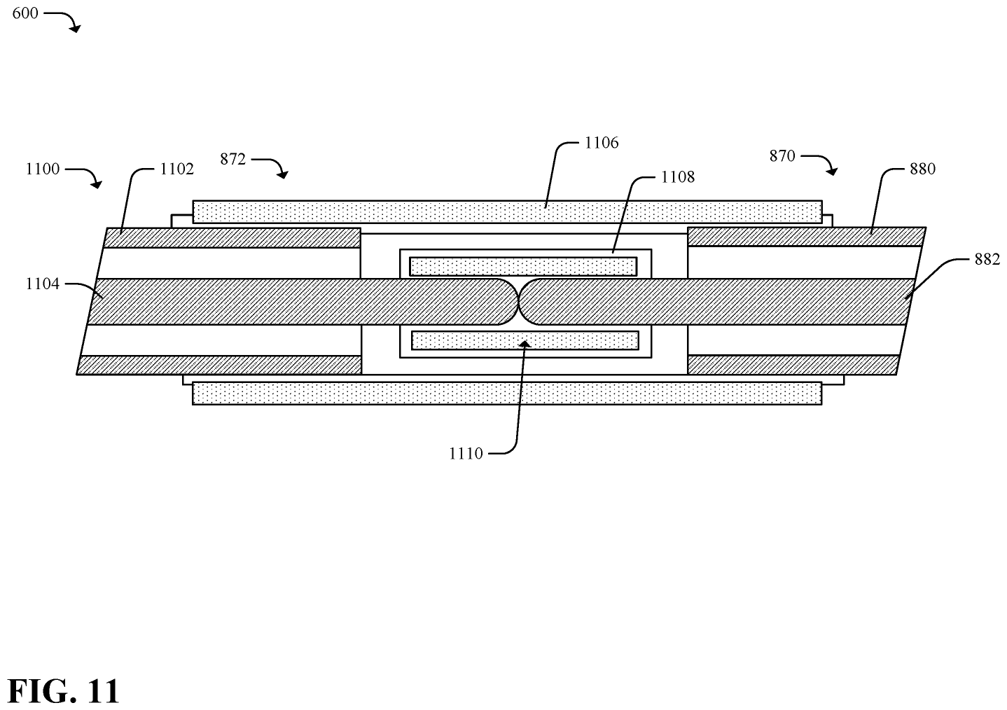

With embodiments, such as generally illustrated in FIG. 11, the second end 872 of the coupling device 600 can be configured to connect to an additional cable 1100, which can form a cable-to-cable low-loss connection between two superconducting cables 860. In examples, such a cable-to-cable low-loss connection can extend the range that which quantum processors can be connected. The outer layer 880 of the one or more cables 860 can be configured to connect to a shield 1102 of the additional cable 1100 and the inner layer 882 can be configured to connect to a center core 1104 of the additional cable 1100. Further, a connecting portion 1106 can mechanically support the connection between the one or more cables 860 and the additional cable 1100. The connection portion 1106 can be a metal tube that can be connected with the outer layer 880 via a superconducting coating layer. Additionally, the inner layer 882 of the one or more cables 860 can be coupled with a center core 1104 (e.g., conductive core) of the additional cable 1100. A center connecting portion 1110 can be electrically connected with the inner layer 882 and the center core 1104, which can be a metal tube including a layer of superconducting solder 1108. In this manner, any number of low-loss cables 860 including any variety of lengths can be connected via the coupling device extending the scalability of quantum systems.

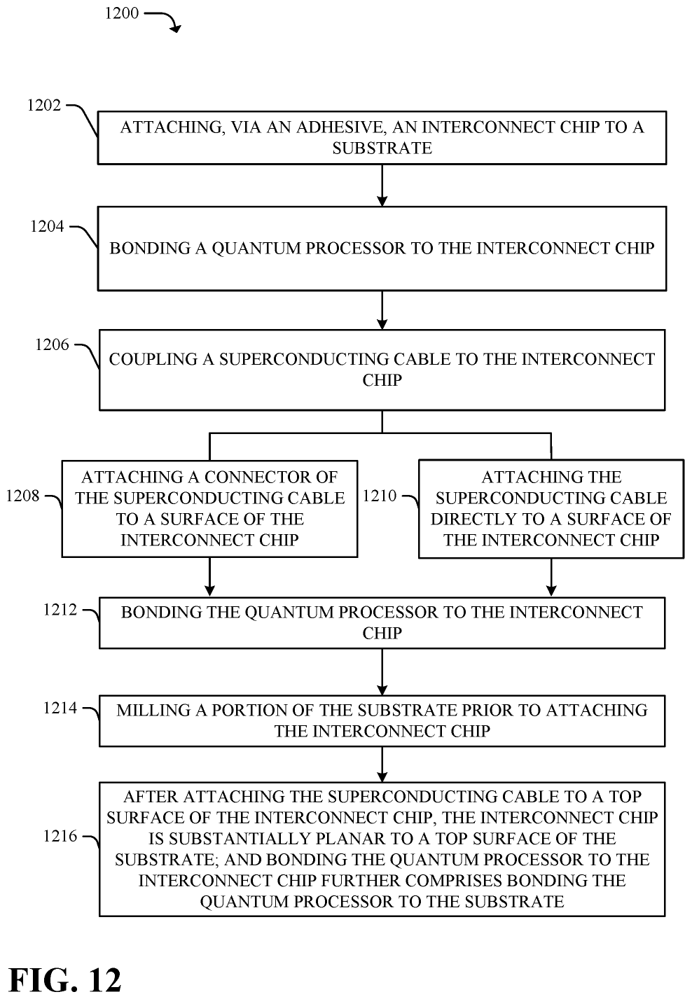

FIG. 12 illustrates a flow diagram of an example, non-limiting method 1200 to facilitate assembling the interconnect chip and L-coupler system in accordance with one or more embodiments described herein. Repetitive description of like elements and/or processes employed in respective embodiments is omitted for sake of brevity.

At 1202, the non-limiting method 1200 to facilitate assembling the interconnect chip and L-coupler system can comprise attaching, via an adhesive, a interconnect chip to a substrate.

Further, in embodiments, at 1204, the method 1200 to facilitate assembling the interconnect chip and L-coupler system can comprise bonding a quantum processor to the interconnect chip.

At 1206, additionally, the method 1200 to facilitate assembling the interconnect chip and L-coupler system can comprise coupling a superconducting cable to the interconnect chip.

At 1208, the non-limiting method 1200 to facilitate assembling the interconnect chip and L-coupler system can comprise attaching a connector of the superconducting cable to a surface of the interconnect chip. Additionally or alternatively, the non-limiting method 1200 can comprise attaching the superconducting cable directly to a surface of the interconnect chip.

At 1212, the non-limiting method 1200 to facilitate assembling the interconnect chip and L-coupler system can comprise bonding the quantum processor to the interconnect chip.

At 1214, the non-limiting method 1200 to facilitate assembling the interconnect chip and L-coupler system can comprise milling a portion of the substrate prior to attaching the interconnect chip.

At 1216, the non-limiting method 1200 to facilitate assembling the interconnect chip and L-coupler system can comprise wherein after attaching the superconducting cable to a top surface of the interconnect chip, the interconnect chip can be substantially planar to a top surface of the substrate. Further, the non-limiting method 1200 can further comprise wherein bonding the quantum processor to the interconnect chip can comprise bonding the quantum processor to the substrate.

Aspects of the one or more embodiments described herein are described herein with reference to flowchart illustrations or block diagrams of methods, apparatus (systems), and devices according to one or more embodiments described herein. It will be understood that each block of the flowchart illustrations or block diagrams, and combinations of blocks in the flowchart illustrations or block diagrams, can be implemented by computer readable program instructions. These computer readable program instructions can be provided to a processor of a general purpose computer, special purpose computer or other programmable data processing apparatus to produce a machine, such that the instructions, which execute via the processor of the computer or other programmable data processing apparatus, create means for implementing the functions/acts specified in the flowchart or block diagram block or blocks. These computer readable program instructions can also be stored in a computer readable storage medium that can direct a computer, a programmable data processing apparatus or other devices to function in a particular manner, such that the computer readable storage medium having instructions stored therein comprises an article of manufacture including instructions which implement aspects of the function/act specified in the flowchart or block diagram block or blocks. The computer readable program instructions can also be loaded onto a computer, other programmable data processing apparatus or other device to cause a series of operational acts to be performed on the computer, other programmable apparatus or other device to produce a computer implemented process, such that the instructions which execute on the computer, other programmable apparatus or other device implement the functions/acts specified in the flowchart or block diagram block or blocks.

The flowcharts and block diagrams in the figures illustrate the architecture, functionality, and operation of possible implementations of systems, computer-implementable methods or computer program products according to one or more embodiments described herein. In this regard, each block in the flowchart or block diagrams can represent a module, segment or portion of instructions, which comprises one or more executable instructions for implementing the specified logical function(s). In one or more alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams or flowchart illustration, and combinations of blocks in the block diagrams or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer or computers, those skilled in the art will recognize that the one or more embodiments herein also can be implemented in combination with other program modules. Generally, program modules include routines, programs, components, data structures or the like that perform particular tasks or implement particular abstract data types. Moreover, those skilled in the art will appreciate that the inventive computer-implemented methods can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics or the like. The illustrated aspects can also be practiced in distributed computing environments in which tasks are performed by remote processing devices that are linked through a communications network. However, some, if not all aspects of the one or more embodiments can be practiced on stand-alone computers. In a distributed computing environment, program modules can be located in both local and remote memory storage devices.

As used in this application, the terms “component,” “system,” “platform,” “interface,” or the like, can refer to or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program or a computer. By way of illustration, both an application running on a server and the server can be a component. One or more components can reside within a process or thread of execution and a component can be localized on one computer or distributed between two or more computers. In another example, respective components can execute from various computer readable media having various data structures stored thereon. The components can communicate via local or remote processes such as in accordance with a signal having one or more data packets (e.g., data from one component interacting with another component in a local system, distributed system or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, where the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units.

Herein, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory or memory components described herein can be either volatile memory or nonvolatile memory or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM) or Rambus dynamic RAM (RDRAM). Additionally, the disclosed memory components of systems or computer-implemented methods herein are intended to include, without being limited to including, these and any other suitable types of memory.

What has been described above include mere examples of systems and computer-implemented methods. It is, of course, not possible to describe every conceivable combination of components or computer-implemented methods for purposes of describing the one or more embodiments, but one of ordinary skill in the art can recognize that many further combinations and permutations of the one or more embodiments are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the one or more embodiments provided herein have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A system, comprising:
a quantum processor comprising a plurality of qubits;
one or more interconnect chips bonded to the quantum processor; and
one or more cable connections coupled to the one or more interconnect chips, wherein the one or more interconnect chips comprise one or more signal routings from the one or more cable connections to the quantum processor wherein a first signal can pass from the one or more cable connections to at least one of the plurality of qubits.

2. The system of claim 1, wherein the quantum processor is bonded to the one or more interconnect chips.

3. The system of claim 1, wherein the quantum processor is bonded to a substrate, and wherein a second signal passes from the substrate to the quantum processor.

4. The system of claim 3, wherein the one or more interconnect chips are bonded to the substrate via an adhesive.

5. The system of claim 4, wherein the substrate further comprises a milled portion having a surface beneath a top surface of the substrate, and wherein the one or more interconnect chips are bonded to the milled portion.

6. The system of claim 5, wherein a top surface of the one or more interconnect chips is substantially coplanar with the top surface of the substrate.

7. The system of claim 6, wherein the one or more cable connections comprise a soldered element.

8. The system of claim 7, wherein the soldered element is soldered directly to the one or more interconnect chips.

9. The system of claim 1, wherein the one or more cable connections comprise a reusable connection.

10. The system of claim 9, wherein the reusable connection comprises an outer layer comprising a machinable solderable metal and an inner layer comprising a solderable metal, wherein the reusable connection is configured to receive at least a center conductor of a coax cable.

11. The system of claim 10, wherein a solder material inside the reusable connection electrically connects a received coax cable to the one or more signal routings.

12. The system of claim 11, wherein the one or more cable connections are configured to receive a low-loss cable.

13. The system of claim 1, further comprising one or more through substrate vias coupled to a ground plane from the one or more interconnect chips.

14. The system of claim 1, wherein the one or more cable connections are configured to receive a superconducting cable.

15. The system of claim 1, wherein the quantum processor comprises an interposer bonded to a quantum chip.

16. A method comprising:
attaching, via an adhesive, a interconnect chip to a substrate;
bonding a quantum processor to the interconnect chip; and
coupling a superconducting cable to the interconnect chip.

17. The method of claim 16, further comprising:
attaching the superconducting cable directly to a surface of the interconnect chip.

18. The method of claim 16, further comprising:
attaching a connector of the superconducting cable to a surface of the interconnect chip.

19. The method of claim 16, further comprising:
bonding the quantum processor to the interconnect chip.

20. The method of claim 16, further comprising:
milling a portion of the substrate prior to attaching the interconnect chip.

21. The method of claim 20, wherein after attaching the interconnect chip to a top surface of the interconnect chip is substantially planar to a top surface of the substrate, and wherein bonding the quantum processor to the interconnect chip further comprises bonding the quantum processor to the substrate.

22. A coupling device comprising:
an outer cylinder comprising a machinable metal and a solderable metal, wherein the coupling device is configured to receive a first cable at a first end of the coupling device.

23. The coupling device of claim 22, wherein a second end of the coupling device is capable of being soldered to a substrate.

24. The coupling device of claim 22, wherein a second end of the coupling device is capable of receiving a second cable.

25. The coupling device of claim 22, further comprising an inner cylinder comprising the machinable metal and the solderable metal, wherein the outer cylinder is configured to connect to a shield of the first cable, and wherein the inner cylinder is configured to connect to a center core of the first cable.
